(19) United States
(12) Patent Application Publication
(10) Pub. No.: US 2010/0294531 A1
(43) Pub. Date: Nov. 25, 2010

(54) Motor Vehicle Power Cable

(75) Inventor: Claus Wefers, Aachen (DE)

Correspondence Address: Sunstein Kann Murphy & Timbers LLP, 125 SUMMER STREET, BOSTON, MA, 02110-1618, US

(73) Assignee: AUTO KABEL MANAGEMENTGESELLSCHAFT MBH, Hausen i.W. (DE)

(21) Appl. No.: 12/663,985

(22) PCT Filed: Mar. 7, 2008
(86) PCT No.: PCT/EP2008/052761

§ 371 Date: Jan. 13, 2010

(30) Foreign Application Priority Data
Jun. 13, 2007 (DE) 10 2007 027 858.8

(51) Int. Cl. H01B 7/00; H05K 13/00

(52) U.S. Cl. 174/102 R; 29/854

(57) ABSTRACT

A motor vehicle power cable comprises at least one first flat-conductor element (10) surrounded by at least one first insulation element (14a). The motor vehicle power cable further comprises at least one second flat-conductor element (12) surrounded by at least one second insulation element (14b), and at least one shielding element (16) surrounding the at least one first insulation element (14a) and the at least one second insulation element (14b). In addition to this, the first flat-conductor element (10) surrounded by the first insulation element (14a) and the second flat-conductor element (12) surrounded by the second insulation element (14b) are arranged in such a way that wide surfaces of the flat-conductor elements (10, 12) lie on one another.

The application relates to a motor vehicle power cable with at least one first flat-conductor element surrounded by at least one first insulation element, at least one second flat-conductor element surrounded by at least one second insulation element, and at least one shielding element surrounding the at least one first insulation element and the at least one second insulation element. The application further relates to the use of such a motor vehicle power cable in a vehicle with electric engine.

Motor vehicles today have on-board networks with a large number of electrical consuming components. Good energy distribution is therefore becoming more and more important.

With motor vehicles with electric motors in particular, such as hybrid vehicles for example, good energy distribution is important. With these vehicles very high voltages (e.g. 60 V to 1 kV) and currents (e.g. 100 A and more) are required for the engine. The energy for the electric motor is supplied by high voltage batteries. Since the electric motor is operated with AC voltage, however, an inverter is additionally connected between the energy storage unit providing the direct current and the electric motor.

Particular attention must be paid to the power cable used for the transfer of the high currents and voltages. Such a power cable must have a high current-carrying capacity.

Due to the high currents and voltages, however, undesirable electromagnetic fields are generated. In order to avoid interference with consuming components in the vehicle's on-board network, for example, power cables in general have shielding. This shielding serves to prevent electromagnetic radiation from the power cable.

From the prior art, only shielded copper round conductors are known for the transfer of energy. A disadvantage with these conductors, however, is that they require a large installation space due to their diameter. The weight of such a conductor is also relatively high.

An alternative to round conductors are flat cables. Flat cables can have less weight and a lower installation space requirement due to their lower height. However, these cables are used in general for communications transfer. Therefore, flat cables from the prior art provide only low capacity for carrying current.

In addition to this, known flat cables at higher current values incur radiated electromagnetic interference which is not acceptable.

Therefore, the application is based on the technical object of providing a motor vehicle power cable which has a low weight and installation height and, at the same time, good electromagnetic compatibility.

This and other objects are achieved according to the application by a motor vehicle power cable with at least one first flat-conductor element surrounded by at least one first insulation element. The motor vehicle power cable further comprises at least one second flat-conductor element surrounded by at least one second insulation element, and at least one shielding element surrounding the at least one first insulation element and the at least one second insulation element. In addition to this, the first flat-conductor element surrounded by the first insulation element and the second flat-conductor element surrounded by the second insulation element are arranged in such a way that wide surfaces of the flat-conductor elements lie on one another.

The cable according to the application can be used in motor vehicles for the transfer of energy. The motor vehicle power cable has at least two flat-conductor elements as electricity conductors. These conductors can have a rectangular cross-sectional surface. It has been recognised that conductors with such a cross-sectional surface are particularly well-suited to a transfer of energy due to a high current-carrying capacity. Depending on the shape factor, a flat conductor can carry up to 40% more current than a round conductor of the same cross-sectional surface. With a rectangular cross-sectional surface, the surface of a flat-conductor element is greater than that of a round conductor of the same cross-section. This greater surface leads to better heat radiation, which takes place essentially by convection. As a result, the current-carrying capacity of a flat-conductor element can be higher.

A twin-conductor structure in particular, which because of its thermal coupling initially has a lower current-carrying capacity than a single conductor, through the design according to the application, as a flat cable with two flat-conductor elements, can carry the same current as two separate round conductors.

Due to the rectangular cross-sectional surface, flat-conductor elements in general have two opposed wide surfaces and two opposed narrow surfaces. In the rare special case of a square conductor, all surfaces of a flat-conductor element are of equal size. Such a two-core motor vehicle power cable makes installation in a motor vehicle substantially easier.

Each of the flat-conductor elements is surrounded by at least one insulation element. For example, an insulation element can be applied by extrusion, adhesive bonding, vapour depositing, or spraying on. Other types of connection are possible. The insulation elements can adhere to the flat-conductor elements but not to one another. The flat-conductor elements with the respective insulation element can move against one another. As a result, good bending properties of the motor vehicle power cable are achieved. In addition to this, no electrical contact takes place between the two flat-conductor elements. The insulation elements can also be formed single-pieced.

In order to prevent electromagnetic radiation, the motor vehicle power cable has a shielding element. Shielding is necessary in order not to interfere with other signals and components. In addition to this, the shielding element can be used as a ground cable. This shielding element surrounds the two flat-conductor elements including the insulation elements.

It has been recognised that a low structural height is achieved when the flat-conductor elements are arranged in such a way that their wide surfaces lie on one another. Such a motor vehicle power cable can be laid easily in a motor vehicle and with only very small installation space requirement. This design also guarantees improved transfer behaviour due to improved transfer impedance. Significant weight advantages are also incurred in relation to conventional power cables.

Good shielding of motor vehicle power cables is in general difficult to achieve. It has been recognised that better shielding, and therefore better electromagnetic compatibility can be achieved if the flat-conductor elements are, according to one embodiment, electromagnetically coupled to one another in such a way that the distant fields radiated by the flat-conductor elements cancel out one another. This can be the case in particular if the flat-conductor elements have a current counter-flow. The B-fields of the two conductors cancel out one another in the distant area, because they are in counter-direction to one another. If the motor vehicle power cable is used, for example, for the transfer of currents for supplying energy to an electric motor, one flat-conductor element can be used as the positive conductor and the other flat-conductor element as the negative conductor. With electrical vehicles in particular, high DC currents are used, wherein the outward and return conductor are formed by the cable according to the application. Both conductors therefore radiate at least one magnetic field. In practice, in addition to this, the fact cannot be avoided that interference signals are coupled onto the conductors as harmonics. It has been recognised, however, that due to the arrangement according to the application the outcoupling of interferences can essentially avoided, since the interferences also cancel out one another. The radiated magnetic fields of the two cables also approximately cancel out one another, because these fields have a′ mutually opposed direction. As a consequence, an improved electromagnetic compatibility can be achieved.

According to one exemplary embodiment, the flat-conductor elements have a distance interval from one another of at least 0.2 mm, preferably 1 mm. This close arrangement, and associated with this a close and good electromagnetic coupling of the conductor elements with one another, cause both optimised transfer behaviour and optimised radiation behaviour (EMC). With a close coupling of this nature, the undesirable fields cancel each other out almost entirely.

The flat-conductor elements can have a current-carrying capacity of at least 100 A. However, requirements for sustained currents of more than 2000 A can be met by another dimensioning of the motor vehicle power cable, in particular of the cross-section of the flat-conductor elements.

According to one exemplary embodiment, the motor vehicle power cable has a rectangular cross-sectional surface. For example, the motor vehicle power cable can have a height of 12 mm and a width of 25 mm. The dimensions can differ, however. The edges of such a cable can be rounded.

Among other things, the dimensions referred to depend on the dimensions of the flat-conductor elements used. These can have a cross-sectional surface of at least 5 mm², preferably 50 mm². The size of the cross-sectional surface can be based, for example, on requirements for a desired and required current-carrying capacity.

Differences in potential of between 60 V and 1000 V can occur between the flat-conductor elements. At least one of the insulation elements can be formed in such a way that a disruptive discharge due to the high voltage can be reliably avoided. The insulation elements can be formed of plastic.

In particular, polyamides, such as PA 12, can be used due to their good insulating and manufacturing properties. The insulation elements can have a thickness of at least 0.1 mm, preferably 0.5 mm.

Moreover, the first and the second insulation elements can be made as one piece from one insulation element. The individual insulation element can be arranged as adhering or not adhering to the flat-conductor elements. In the non-adhering arrangement, the flat-conductor elements can move against one another. Good bending properties can also be guaranteed. Moreover, the single-piece insulation element can be formed thicker than the first and the second insulation element. Just as good a coupling can be achieved in comparison with these two insulation elements.

According to one exemplary embodiment, the shielding element can be surrounded by a third insulation element. This insulation element can also be made from plastic. This insulation element serves as a protective sheath, and can have the effect, among other things, that damage to the motor vehicle power cable can be prevented.

The shielding element can be made from a sheet. A sheet has the advantage that it encloses the flat-conductor elements tightly and can also shield high-frequency radiation. It is specifically in the interaction of this shielding with the electromagnetic coupling, according to the application, of the flat-conductor elements that a very good electromagnetic compatibility is guaranteed. In particular at a thickness of at least 0.1 mm of the shielding element, a very good shielding effect is achieved. If a sheet is used as shielding element, a good flexibility of the motor vehicle power cable can still be guaranteed. This is also the case for thicknesses of more than 0.1 mm, for example 0.2 mm.

In one exemplary embodiment, the shielding element is formed from a non-ferrous metal or an alloy not containing iron. The shielding element can be made, for example, from copper or its alloys.

In addition to this, the shielding element can be wound with an overlap of at least 10%, preferably 50%. With a winding, if the overlap is too small, the shielding may not be completely tight. Moreover, if the overlap is only small, then if slight movements occur during manufacture, holes may occur in the shielding. Holes in the shielding are reliably avoided by an overlap according to the application.

According to a further exemplary embodiment, the shielding element is formed from at least one film and at least one braiding. The braiding can be made, for example, from copper or aluminium, and the foil from aluminium. The braiding serves in this case predominantly to shield low-frequency fields. However, the radiation from high-frequency fields is not adequately prevented by a braiding, since the braiding is not entirely tight. However, braiding does have good flexibility. In addition, a film, e.g. a thin sheet, can be used. This film serves to shield the high-frequency fields, and likewise has good flexibility. Overall, a more reliable radiation protection is obtained, with good flexibility properties at the same time.

It is also possible for at least one flat-conductor element to be made from aluminium. Other non-ferrous metals are also possible, however, such as copper. In comparison with other metals, such as copper, aluminium has the advantage of perceptibly lesser weight. By contrast, copper has better electrical conductivity properties. It has been recognised, however, that with the motor vehicle power cable according to the application, due to a greater cross-sectional surface of the flat-conductor elements, equally good conductivity properties can be achieved and, at the same time, a weight reduction of up to 40% can be achieved. Moreover, an aluminium flat-conductor element with the same electrical resistance as a copper flat-conductor element can have a higher current-carrying capacity. As a result, with a fixed current-carrying capacity, the cross-section can be reduced again in comparison with round conductors and/or copper conductors.

According to a further exemplary embodiment, the motor vehicle power cable has a minimum bending radius in the orthogonal direction to the wide surface of the motor vehicle power cable of at least 5 mm, preferably 12 mm. Likewise, the motor vehicle power cable can have a minimum bending radius in the orthogonal direction to a narrow surface of the motor vehicle power cable of at least 25 mm, preferably 38 mm. Simple laying in the engine compartment, in particular with narrow radii, can be guaranteed.

A further aspect of the application is the use of the motor vehicle power cable in a vehicle with electric engine. For example, the vehicle can be a hybrid vehicle. With an electrically driven vehicle in particular, power cables with a high current-carrying capacity are used, since an electric motor is operated at high voltages and currents. Likewise, the weight in particular is a major factor of such a vehicle. The motor vehicle power cable can in particular be used as a battery cable in a vehicle with electrical drive.

The application is explained in greater detail hereinafter on the basis of a drawing showing an exemplary embodiment. The drawing shows:

FIG. 1 A diagrammatic sectional view of a first exemplary embodiment of a motor vehicle power cable,

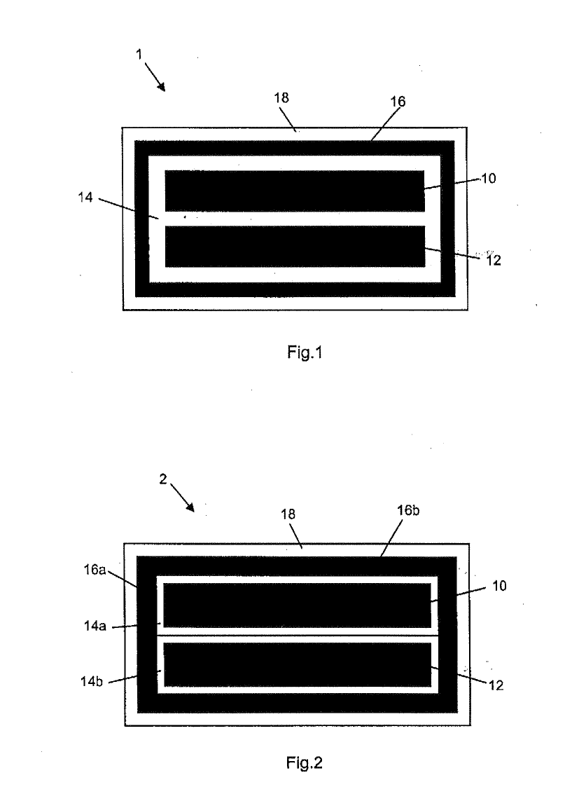

FIG. 2 A diagrammatic sectional view of a second exemplary embodiment of a motor vehicle power cable,

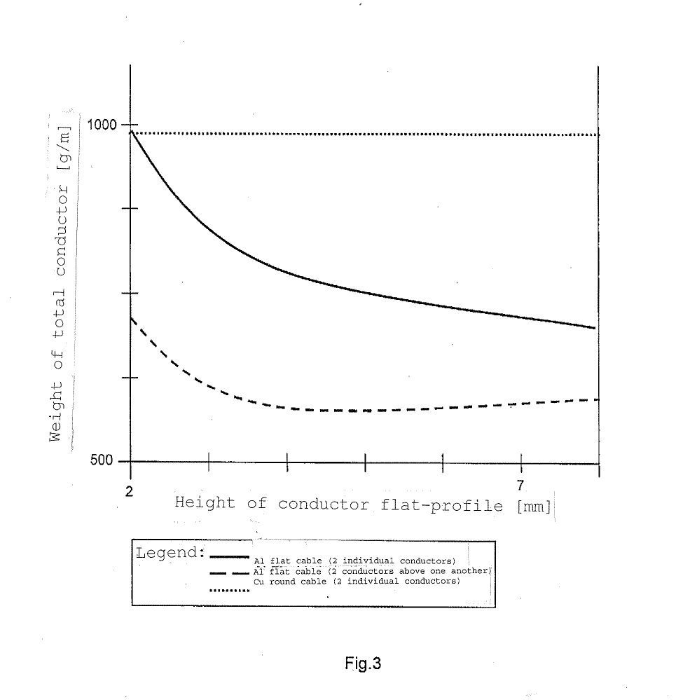

FIG. 3 A height/weight diagram.

The structure, represented in the figures, of the motor vehicle power cable according to the application has in particular a low structural height and, moreover, a very good radiation behaviour.

Where possible, the same reference numbers have been used for the same elements in FIGS. 1 and 2.

Represented in FIG. 1 is a simplified sectional view of a first exemplary embodiment of a motor vehicle power cable 1.

The first flat-conductor element 10 is arranged with its wide surface over the wide surface of the second flat-conductor element 12. The flat-conductor elements 10, 12 can be formed from aluminium. Further, the flat-conductor elements 10, 12, are surrounded by an insulation element 14, and electrically isolated from one another by this insulation element 14. The insulation element 14 can be made from plastic, such as PA 12, and can be applied around the flat-conductor elements 10, 12, by spraying on. The connections can at least be of positive fit.

A shielding element 16 surrounds the insulation element 14 in turn. The shielding element 16 can be a sheet. The sheet can additionally be wound with an overlap of 50%. Finally, a protective sheath 18 is also applied around the shielding element 16. This can be made from plastic and have a thickness, for example, of 1 mm. All elements 10 to 18 involved can be connected to one another in positive fit.

The simplified sectional view shown in FIG. 2 of the motor vehicle power cable 2 differs from the previous example in that, on the one hand, the first flat-conductor element 10 is surrounded by a first insulation element 14a, and the second flat-conductor element 12 is surrounded by a second insulation element 14b. For the manufacture of the motor vehicle power cable 2 with at least two insulation elements, the advantage is derived that in the first instance each of the flat-conductor elements 10, 12 can be surrounded by an insulation layer 14a, 14b. These elements can then be joined to one another in the manner represented.

On the other hand, the two exemplary embodiments differ in that the shielding element 16 comprises a film 16a and a braiding 16b. The film 16a can be of aluminium, while the braiding 16b can be of copper.

In both FIGS. 1 and 2 the motor vehicle power cables 1, 2, are of rectangular shape, wherein the edges can be rounded. The dimensions of the motor vehicle power cables 1, 2, such as width and height, depend, among other things, on the dimensions of the flat-conductor elements 10, 12.

The motor vehicle power cable 1, 2, from FIG. 1 or 2 can be used, for example, for the transfer of current in a hybrid vehicle. The first flat-conductor element 10 can be used as a positive or outward conductor and the second flat-conductor element 12 as the negative or return conductor. A disruptive discharge due to the differences in potential of up to 1000 V arising between the flat-conductor elements 10, 12 is avoided by the insulation elements 14, 14a, 14b.

The currents arising, for example of 100 A and more, produce B-fields and cause a radiation of these fields. In addition to this, undesirable harmonics which are coupled onto the flat-conductor elements 10, 12, engender further interference signals. Good coupling resistance and good radiation behaviour can be achieved by the represented close coupling of the flat-conductor elements 10, 12, to one another. For example, the insulation elements 14a, 14b have a thickness of 0.5 mm in each case, such that there is a distance interval of 1 mm between the flat-conductor elements 10, 12. As a result of this arrangement according to the application and a current counter-flow, distant fields which occur essentially cancel one another out. In addition to this, further radiation by the shielding element 16, 16a, 16b is prevented. The result is a motor vehicle power cable with an optimised transfer behaviour and radiation behaviour.

FIG. 3 further shows a height/weight diagram. In this connection, the total weight of three conductor examples with the same electrical conductivity properties is represented as a function of the height. The copper round cable comprises two individual conductors, and each individual conductor has a diameter of 12 mm. This diameter is constant. As a consequence, the total weight of the copper round cable is also constant and amounts to approximately 1000 g/m. In addition to this, two flat cables are illustrated in the diagram. One of these is a flat cable consisting of two aluminium single flat conductors. From the diagram it can be seen that, when the height of the cable is low (approx. 2 mm), no weight advantages are gained in relation to the copper round cable. With greater heights (7 mm), weight advantages of up to 250 g are obtained. The other illustration is of an aluminium motor vehicle power cable according to the application. The enormous weight advantages (up to about 410 g) can be clearly appreciated, despite a small overall height of the motor vehicle power cable in relation to the copper round cable, but also in relation to the aluminium individual flat conductor.

As a result of the described structure of the motor vehicle power cable, a motor vehicle power cable is obtained with optimum transfer behaviour and radiation behaviour. In addition to this, a compact structure is guaranteed due to low structural height and a low weight.

It is self-explanatory that the exemplary embodiments described are only a few of a large number of possible exemplary embodiments. For example, other materials and/or additional insulation elements and/or additional shielding elements can be used.

1-23. (canceled)

24. A motor vehicle energy cable comprising:
at least one first flat-conductor element surrounded by at least one first insulation element;
at least one second flat-conductor element surrounded by at least one second insulation element; and
at least one shielding element surrounding the at least one first insulation element and the at least one second insulation element,
wherein the first flat-conductor element surrounded by the first insulation element and the second flat-conductor element surrounded by the second insulation element are arranged in such a way that wide surfaces of the flat-conductor elements lie on one another, and that the insulation elements are moveable against each other to improve bending properties of the motor vehicle energy cable.

25. The motor vehicle power cable of claim 24, wherein the flat-conductor elements have a current counter-flow, such that the flat-conductor elements are electromagnetically decoupled in such a way that distant fields radiated by the flat-conductor elements substantially cancel one another out.

26. The motor vehicle power cable of claim 24, wherein during an operational state of the motor vehicle, the flat-conductor elements have a current counter-flow of such a nature that the distant fields radiated by the flat-conduct elements cancel one another out.

27. The motor vehicle power cable of claim 24, wherein the flat-conductor elements have a distance interval from one another of at least 0.2 mm (millimeters).

28. The motor vehicle power cable of claim 24, wherein the flat-conductor elements have a current-carrying capacity of at least 100 A (amperes).

29. The motor vehicle power cable of claim 24, wherein the motor vehicle power cable has a rectangular cross-section.

30. The motor vehicle power cable of claim 24, wherein at least one flat-conductor element has a cross-sectional surface of at least 5 mm².

31. The motor vehicle power cable of claim 24, wherein at least one of the insulation elements is formed in such a way that a dielectric strength having a difference in potential of 60 V to 1000 V is produced between the flat-conductor elements.

32. The motor vehicle power cable of claim 24, wherein the first insulation element and the second insulation element are formed as one piece from one insulation element.

33. The motor vehicle power cable of claim 24, wherein the at least one shielding element is surrounded by at least one third insulation element.

34. The motor vehicle power cable of claim 24, wherein the at least one shielding element comprises at least one sheet.

35. The motor vehicle power cable of claim 24, wherein the at least one shielding element has a thickness of at least 0.1 mm.

36. The motor vehicle power cable of claim 24, wherein the at least one shielding element is made from at least one of a non-ferrous metal, an alloy not containing iron, and a non-ferrous metal and an alloy not containing iron.

37. The motor vehicle power cable of claim 24, wherein the at least one shielding element is wound with an overlap of at least 10%.

38. The motor vehicle power cable of claim 24, wherein the shielding element comprises at least one film and at least one braiding.

39. The motor vehicle power cable of claim 24, wherein the at least one film is made from aluminium and the at least one braiding is made from copper or aluminium.

40. The motor vehicle power cable of claim 24, wherein at least one flat-conductor element is made from aluminium.

41. The motor vehicle power cable of claim 24, wherein the motor vehicle power cable has a minimum bending radius a direction orthogonal to the wide surface of the motor vehicle power cable of at least 5 mm.

42. The motor vehicle power cable of claim 24, wherein the motor vehicle power cable has a minimum bending radius in a direction orthogonal to a narrow surface of the motor vehicle power cable of at least 25 mm.

43. The motor vehicle power cable of claim 24, wherein the flat-conductor elements are non-adhering with the insulation elements, such that the flat-conductor elements are moveable against each other.

44. The motor vehicle power cable of claim 24, wherein the shielding element is wound with an overlap of at least 10% around the insulation elements.

45. A method of connecting electrical components in a motor vehicle having an electric engine, the method comprising
obtaining a motor vehicle power cable including
at least one first flat-conductor element surrounded by at least one first insulation element,
at least one second flat-conductor element surrounded by at least one second insulation element, and
at least one shielding element surrounding the at least one first insulation element and the at least one second insulation element, wherein the first flat-conductor element surrounded by the first insulation element and the second flat-conductor element surrounded by the second insulation element are arranged in such a way that wide surfaces of the flat-conductor elements lie on one another, and that the insulation elements are moveable against each other to improve bending properties of the motor vehicle energy cable; and
connecting the cable to the electrical components.

46. A method according to claim 45 wherein the cable is connected as a battery cable.
